(19) United States
(12) Patent Application Publication
(10) Pub. No.: US 2024/0171123 A1
(43) Pub. Date: May 23, 2024

(54) BALL-NET REFLECTOR FOR BIFACIAL FLOATING PHOTOVOLTAIC SYSTEMS

(71) Applicant: Technische Universiteit Delft, Delft (NL)

(72) Inventors: Hesan ZIAR, Delft (NL); Ugne ZINDZIUTE, Delft (NL); Olindo ISABELLA, Delft (NL)

(73) Assignee: Technische Universiteit Delft, Delft (NL)

(21) Appl. No.: 18/550,849

(22) PCT Filed: Feb. 25, 2022
(86) PCT No.: PCT/NL2022/050113

§ 371 Date: Sep. 15, 2023

(30) Foreign Application Priority Data
Mar. 17, 2021 (NL) 2027763

(51) Int. Cl. H02S 40/22; B63B 35/44; G02B 5/09; G02B 17/00

(52) U.S. Cl. CPC H02S 40/22; B63B 35/44; G02B 5/09; G02B 17/002; B63B 2035/4453

(57) ABSTRACT

The present invention is in the field of a reflector for a bifacial PV-system, typically a floating bifacial PV-system, and a PV-system comprising such a reflector. The floating PV-system is typically provided in a rural environment, or on sea, or on a lake, or the like. Said environment also has an ecological function, for plants and animals typically being present there.

### FIELD OF THE INVENTION

The present invention is in the field of a reflector for a bifacial PV-system, typically a floating bifacial PV-system, and a PV-system comprising such a reflector. The floating PV-system is typically provided in a rural environment, or on sea, or on a lake, or the like. Said environment also has an ecological function, for plants and animals typically being present there.

### BACKGROUND OF THE INVENTION

A solar cell, or photovoltaic (PV) cell, is an electrical device that converts energy of light, typically sun light (hence “solar”), directly into electricity by the so-called photovoltaic effect. The solar cell may be considered a photoelectric cell, having electrical characteristics, such as current, voltage, resistance, and fill factor, which vary when exposed to light and which vary from type of cell to type.

Solar cells are described as being photovoltaic irrespective of whether the source is sunlight or an artificial light. They may also be used as photo detector.

When a solar cell absorbs light it may generate either electron-hole pairs or excitons. In order to obtain an electrical current charge carriers of opposite types are separated. The separated charge carriers are “extracted” to an external circuit, typically providing a DC-current. For practical use a DC-current may be transformed into an AC-current, e.g. by using a transformer. Typically solar cells are grouped into an array of elements. Various elements may form a panel, and various panels may form a system.

Wafer based c-Si solar cells contribute to more than 90% of the total PV market. According to recent predictions, this trend will remain for the upcoming years towards 2030 and many years beyond. Due to their simplified process, conventional c-Si solar cells dominate a large part of the market.

A disadvantage of solar cells is that the conversion per se is not very efficient, typically, for Si-solar cells, limited to some 20%. Theoretically a single p-n junction crystalline silicon device has a maximum power efficiency of 33.7%. An infinite number of layers may reach a maximum power efficiency of 86%. The highest ratio achieved for a solar cell per se at present is about 47%. For commercial silicon solar cells the record is about 25.6%. In view of efficiency also a backside of a PV-module or solar cell may be used to convert light into electrical power. Such cells are referred to as bifacial solar cells. The back side of these bifacial solar cells makes use of reflected or divergent light, such as of a surface underneath a bifacial solar cell, or a surface in the near vicinity of the solar cell.

Floating photovoltaic (PV) systems installation rate is increasing as a result of competition of food and housing sectors with PV sector over land. On the other hand, bi-facial PV systems are also a considerable trend in the PV industry as they offer more electrical yield for the same occupied area. As a result, combining bifacial PV and floating PV leads to less levelized cost of electricity (LCOE). However, bifacial are only effective when the surface beneath the PV modules, that reflect sunlight back to the rear side of the PV module, is has a high albedo. However, for floating PV systems, albedo of water is very low, around 6%. There are thus a very limited number of floating bifacial PV systems around the World and they do not usually use a reflector based on the above misunderstanding that water is reflecting a lot of light, which is simply not true. As an alternative solution a solid monolithic reflector could be used. However, those reflectors are bulky, expensive, difficult to install, quickly bio-fouled, and cast uniform shading on the water that effects water-ecosystem negatively. In addition, over time such a plate gets polluted, such as with dirt and excrements of (water) animals, and the reflectance drops significantly.

Some prior art may be referred to. US 2020/389120 A1 recites a floating module for producing electricity, comprising: at least one photovoltaic panel, and a floating framework on which the panel is mounted, wherein the photovoltaic panel comprises an upper face and a lower face which are capable of generating electricity by photovoltaic effect, and wherein the floating module further comprises a reflective device capable of reflecting light rays towards the lower face of the panel, the reflective device comprising a plurality of floating reflective balls and/or a tarpaulin which is attached to the framework. DE 10 2018 119842 A1 recites a floating solar panel substructure comprising multiple floats that are interconnected by mounting systems, lying therebetween. Each of said mounting systems, is used to fasten one solar panel. In order to provide a floating solar installation substructure, which affords good access to the solar panels, while following the motion of the surface of the water without any difficulty, the floats, and the mounting systems, are fastened so that they are adjacent to one another. In addition, the two outlying floats, of each solar panel substructure are rigidly connected to their respective adjacent mounting systems, whereas at least one float lying between the outlying floats, in the solar panel substructure is connected, by means of articulations, to its respective mounting system, on either side. The individual articulation, allows a rocking motion between the mounting systems, and their respective at least one float lying therebetween. US 2016/059938 A1 recites modular floating platforms configured to be joined together to form a cover over surfaces of natural and artificial bodies of water and other liquids, for reducing evaporation and other purposes. The floating platforms may be motorized and provided with remote control systems, so that the platforms may be assembled together on command to provide uniform coverage of the surface of the body of water. The floating platforms are optionally capable of solar and wind power collection. The platforms are useful for covering mining tailing storage ponds.

The present invention relates to an improved reflector for a bifacial PV-system and various aspects thereof which overcomes one or more of the above disadvantages, without jeopardizing functionality and advantages.

### SUMMARY OF THE INVENTION

The present invention relates in a first aspect to a ball-net reflector according to claim 1, and in a second aspect to a PV-system comprising such a reflector according to claim 17, in particular for floating PV systems. According to roadmap of PV for the Netherlands, it is expected to have 9 GWp of floating PV by 2030, and about 70 GWp by 2050 on inner waters areas and the North Sea. This already provides a great potential. Some advantages are (i) an optimum reflection from the ball-net, such as based on the view factor concept; (ii) a resilience against dirt and fouling, such as by partially filling the balls and such as by fixing the balls with torsion springs which allows the balls to roll over water (up to a certain degree, preferably ±90) and thus clean the ball surface and maintain its reflectivity; and (iii) the ball-net reflector being tuned for water ecology, in particular by having selective voids (missing balls within the net) to let sunlight pass through into the water, which is considered essential for water ecosystem and biomass underneath the floating PV structure.

In an exemplary embodiment the present invention relates to a network of different colour balls, which can be partially filled with water, that can be installed under floating pontoons of the floating photovoltaic systems. It optimally reflects light to the back side of the bifacial photovoltaic system. Such a ball-net is (1) less heavy, (2) cheaper, (3) more flexible, (4) replaceable, (5) does not get bio-fouled because of bird presence, and (6) has tuneable or adaptable reflectance and transmittance, such as by adjusting the colour and size of the balls, to respectively match spectral response of the rear side of the bifacial PV modules and ensure enough light penetration in to the water for the eco-system needs; it therewith mitigates the negative influence on water-ecosystem as a result of continuous casted shadow on a water. The present ball-net reflector as advantages e.g. a much higher reflection of light, such as up to 800 W/m², and typically at least 200-300 W/m², whereas water for instance only has some 10-60 W/m², no problems with pollution, as animals find it hard to stay on a slightly rotating object, and by rotating and by precipitation the reflector is cleaned, and it is ecologically friendly, in that still a significant part of the sunlight can enter a water volume underneath the present reflector. The efficiency of the solar cells is thereby typically increased with 20-30% relative to a typical output of a bifacial system on water, and may be increased up to 80%.

The present ball-net reflector for a bifacial PV-system comprises a plurality of balls, each ball having at least one ball-albedo, therewith functioning as a passive reflector, at least one ball-fixator per ball, the ball-fixator adapted to substantially keep the at least one ball of the plurality of balls into a stationary place, an optional matrix structure with openings adapted to receive the plurality of balls, the at least one ball-fixator attached to the matrix structure or to an adjacent ball, and at least one connector for connecting the ball-net reflector to the bifacial PV-system, which connection may be directly to the bifacial PV-system or indirectly thereto. The matrix may be present, or not. If it is present the present balls can be attached thereto, whereas if it is not, the balls are typically attached to one and another, and as such form a matrix like structure.

The present “ball” may refer to a spherical-like structure, or to any 3D-structure. Typically the structure is at least partly hollow, or fully hollow.

An optimum design for the bifacial yield could require maximizing the two view factors: (i) a first view factor from the ball-net to the sky dome VF_{ball-net→sky} and, (ii) a second view factor from the rear-side of the bifacial PV modules to the ball net (VF_{rear-PV module→ball-net}). For instance, putting the modules close to the ball-net increases the second view factor but reduces the first and vice versa. In mathematical terms, one can may use the following equations: Let's consider a PV array with area A_{PV} installed with angle a and a ball-net with a size of A_{Ball} and installation angle of zero (horizontal). The PV array is installed in a free horizon. Then the relations between the view factors are:

In free horizon, only the tilt angle determines the view factor to the sky done:

VF_{front-PV→sky}=(1+cos α)/2

Summation of view factors is unity:

VF_{Ball→rear-PV}+VF_{Ball→sky}=1

Reciprocity rule of the view factors:

A_{Ball}·VF_{Ball→rear-PV}=A_{PV}·VF_{rear-PV→Ball}

### Therefore:

(A_{PV}/A_{Ball})·VF_{rear-PV→Ball}+VF_{Ball→sky}=1

As can be seen in the last equation, increasing one view factor would reduce the other.

In an example, such as for the system shown in FIG. 7 (the one with the place for ball-net reflector with the trapezoid), the height of the PV modules upper edge from the reflector (trapezoidal shape with bases of 2.02 m and 4.55 m and height of 2.01) is 1.58 m. The PV panel consisted of 6 PV modules with the total size of 4.94 m×2.29 m and tilt angle of 15°. Here are the calculated view factors for this system:

VF_{rear-PV→Ball}=33.1%

VF_{rear-PV→water}=66.9%

The view factor may also be referred to as “shape factor” or “form factor”.
Thereby the present invention provides a solution to one or more of the above mentioned problems.

Advantages of the present description are detailed throughout the description. References to the figures are not limiting, and are only intended to guide the person skilled in the art through details of the present invention.

### DETAILED DESCRIPTION OF THE INVENTION

In an exemplary embodiment of the present ball-net reflector the PV-system comprises 2-2¹⁰ PV-modules, in particular 4-2⁹ PV-modules, more in particular 2⁵-2⁸ PV-modules, so very large systems, and optionally a PV-system supporting structure, such as a frame, or a multitude of supporting structures, such as one supporting structure per PV-module. Supporting structures and/or PV-modules can be fully or partly integrated.

In an exemplary embodiment of the present ball-net reflector the plurality of balls is arranged in a matrix with adjacent balls. In an alternative at least some balls can be left out, creating open spaces, such as for letting light passing through. Or a combination of the two can be made.

In an exemplary embodiment the present ball-net reflector may comprise a first ball and at least one adjacent ball, wherein the at least one adjacent ball has a ball-albedo different from the ball-albedo of the first ball. By varying albedos the power output of the bifacial PV-module can be further optimized.

In an exemplary embodiment of the present ball-net reflector in the matrix the ball-albedo varies in a regular 2D-pattern. As shown in FIG. 1, balls can vary in a hexagonal pattern, using three colours therein.

In an exemplary embodiment of the present ball-net reflector the ball fixator is a string or a spring. Typically balls can be attached by strings or springs or the like to the matrix, e.g. the net.

In an exemplary embodiment of the present ball-net reflector 2-6 ball-fixators per ball are provided, such as 3-5 ball-fixators. For fixing typically a number of fixators are used. A lower number provides somewhat more freedom to the ball or the like, which is advantageous, such as in terms of cleaning.

In an exemplary embodiment of the present ball-net reflector the ball fixator is adapted to provide limited rotation of 1-30 degrees in both an azimuth and altitude direction relative to a gravitational axis. It is preferred to have the balls to rotate somewhat, e.g. for cleaning.

In an exemplary embodiment of the present ball-net reflector a ball each individually is at least partly filled with a filler with a specific mass (volumetric mass density) larger than air, such as water, sand, and combinations thereof, such as 20-70% filled. By filling the balls there floating properties can be adapted, e.g. such that a higher or smaller fraction of the ball is above/below the water surface.

In an exemplary embodiment of the present ball-net reflector each balls individually is substantially spherical, or wherein each ball individually comprises regular faces, such as triangular, pentagonal and hexagonal faces, such as at least partly an icosahedron or a truncated icosahedron, wherein each face may have the same or a different albedo. The “balls” can have many shapes, such as spherical, but also polyhedron, such as with an icosahedron.

In an exemplary embodiment of the present ball-net reflector balls each individually have a diameter of 3-30 cm, preferably 5-25 cm, such as 10-15 cm. Balls are preferably not too large, e.g. in view of cleaning, or getting dirty, and in view of handling, and are preferably not too small.

In an exemplary embodiment of the present ball-net reflector balls each individually float, such as with 40-60% of their surface area above the water. By having a part above the water surface enough albedo is provided, and by having a part below the surface of the water also sufficient cleaning is provided.

In an exemplary embodiment of the present ball-net reflector the at least one connector is a hook. Typically the ball-net is attached to the PV-system, typically in a manner that it is secured in place, and preferably that it can be removed without too much effort.

In an exemplary embodiment of the present ball-net reflector the ball-net reflector has an open area of 10-40% relative to a total area for passing through sunlight. Part of the ball-net reflector can be left open intentionally, for passing sunlight through. Such can be done by selecting a large net with relatively small balls, leaving open spaces without balls, or a combination thereof.

In an exemplary embodiment of the present ball-net reflector a view factor of a rear-side of the bifacial PV-system is 10-50%, preferably 25-40%, such as 30-35%. The summations of all view factors from a surface to its surrounding surface equals to unity. Therefore, the summation of the view factor from the rear side of the PV panel to the ball-net reflector and the view factor from the rear side of the PV panel to the rest of the surfaces equals unity. This is a relatively high view factor.

In an exemplary embodiment of the present ball-net reflector wherein 10-35% of the plurality of balls has a first ball-albedo, and wherein 10-35% of the plurality of balls has a second ball-albedo, and wherein 10-35% of the plurality of balls has a third ball-albedo. For instance, about ⅓ of the balls may have a first colour, about ⅓ of the balls may have a second colour, and about ⅓ of the balls may have a third colour.

In an exemplary embodiment of the present ball-net reflector 10-35% of the plurality of balls has a fourth ball-albedo. Further colours may be added in order to improve the total albedo, or to improve for ambient conditions, or a combination thereof.

In an exemplary embodiment of the present ball-net reflector 10-35% of the plurality of balls has a fifth ball-albedo. Further colours may be added in order to improve the total albedo, or to improve for ambient conditions, or a combination thereof.

In an exemplary embodiment of the present ball-net reflector each ball individually is adapted to reflect solar light or ambient light. The surface of the ball is typically carefully selected, such that solar light or ambient light,, or both, are reflected optimally.

In an exemplary embodiment of the present ball-net reflector each ball individually comprises a coating for diffuse reflection. Suitable coatings are for instance oxides, nitrides, metals, polymers, such as polycarbonate, those comprising nanoparticles, those comprising voids or holes, and combinations thereof, such as of Ti, Zn, Cu, Sn, Si, Al, Au, and Ag. The coating may typically be 0.1-5 μm thick, each. Coatings can be provided by physical vapour deposition, chemical vapour deposition, atomic layer deposition, dip techniques, and the like.

In an exemplary embodiment of the present ball-net reflector each ball individually comprises a textured surface for diffuse reflection, such as with a surface roughness Ra of 10-300 nm, preferably 20-100 nm [measured according to ISO 4287 and ISO 16610-21, e.g. with a Mitutoyo SJ-210].

In an exemplary embodiment of the present ball-net reflector each ball individually is adapted to reflect at least one bandwidth of wavelength, wherein the bandwidth is <300 nm, preferably <200 nm, even more preferably <100nm, wherein bandwidths preferably do not overlap.

In an exemplary embodiment of the present ball-net reflector a central wavelength of a bandwidth of a first ball is 470±20 nm, or wherein a central wavelength of a bandwidth of a second ball is 980±20 nm, or wherein a central wavelength of a bandwidth of a third ball is 900±20 nm, or wherein a central wavelength of a bandwidth of a fourth ball is 850±20 nm, or wherein a central wavelength of a bandwidth of a fifth ball is 1170±20 nm, or wherein a central wavelength of a bandwidth of a sixth ball is 785±20 nm, or wherein a central wavelength of a bandwidth of a seventh ball is 705±20 nm, or wherein a central wavelength of a bandwidth of a eight ball is 675±20 nm, or wherein a central wavelength of a bandwidth of a ninth ball is 630±20 nm, or wherein a central wavelength of a bandwidth of a tenth ball is 360±20 nm, or wherein a central wavelength of a bandwidth of a eleventh ball is 550±20 nm, or wherein a central wavelength of a bandwidth of a twelfth ball is 1050±20 nm, and combinations thereof.

In an exemplary embodiment of the present ball-net reflector each ball individually is adapted to reflect low intensity light, preferably from 1-800 W/m², more preferably from 10-600 W/m², even more preferably from 100-500 W/m², such as from 200-300 W/m².

In an exemplary embodiment of the present ball-net reflector the ball-net reflector is adapted to provide buoyance to the PV-system. As such the PV-system itself can be made less complex, and the present ball-net reflector can contribute to the buoyance.

The invention is further detailed by the accompanying figures and examples, which are exemplary and explanatory of nature and are not limiting the scope of the invention. To the person skilled in the art it may be clear that many variants, being obvious or not, may be conceivable falling within the scope of protection, defined by the present claims.

### SUMMARY OF FIGURES

FIGS. 1-9 show a schematic representation of an example of the present ball-net reflector and aspects thereof.

### DETAILED DESCRIPTION OF FIGURES

1 ball-net reflector
10 ball
11 first ball
12 second ball
13 third ball
20 ball-fixator
30 matrix structure
40 connector
51 Optimized view factor from PV module rear-side to the ball-net and from the ball-net to the sky
52 Textured balls for Lambertian reflection
53 ball fixator with rotation capability
54 frame for ball-net
55 balls can rotate by wave force to clean the dust and debris from the ball surface and maintain a high level of reflection
56 colored balls for spectrally selective reflection optimized for the rear-side PV response of the modules
57 selective voids within the ball-net to let the sunlight pass through to the water and maintain ecological growth

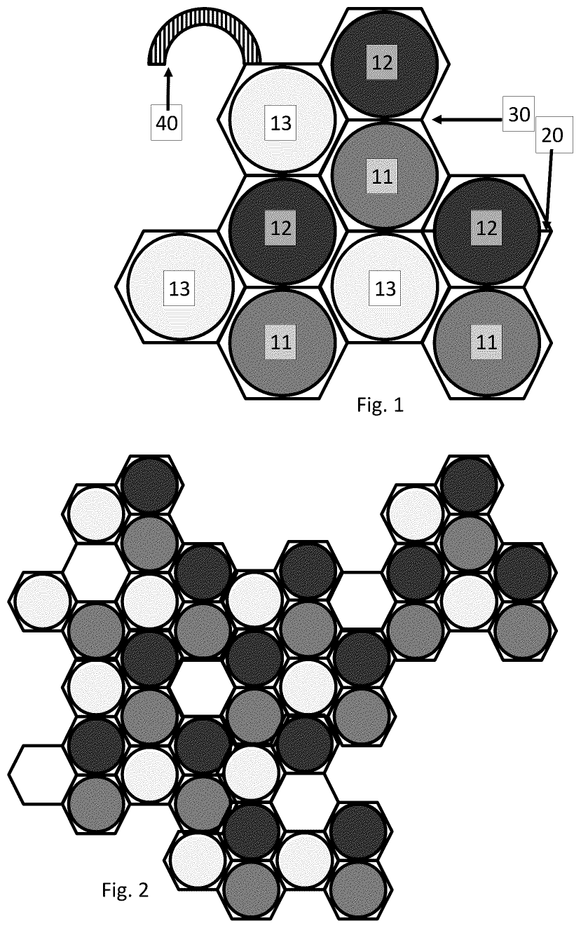

FIG. 1 shows schematics of the present ball-net reflector, with three different colored balls 11,12,13, stacked in a 2D-hexagonal pattern, with a hexagonal matrix structure 30, ball fixators 20 (only a few shown), and a hook connector 40.

FIG. 2 shows schematics of the present ball-net reflector, wherein balls are in a hexagonal matrix, wherein some of the balls are left out, in this case in a regular pattern.

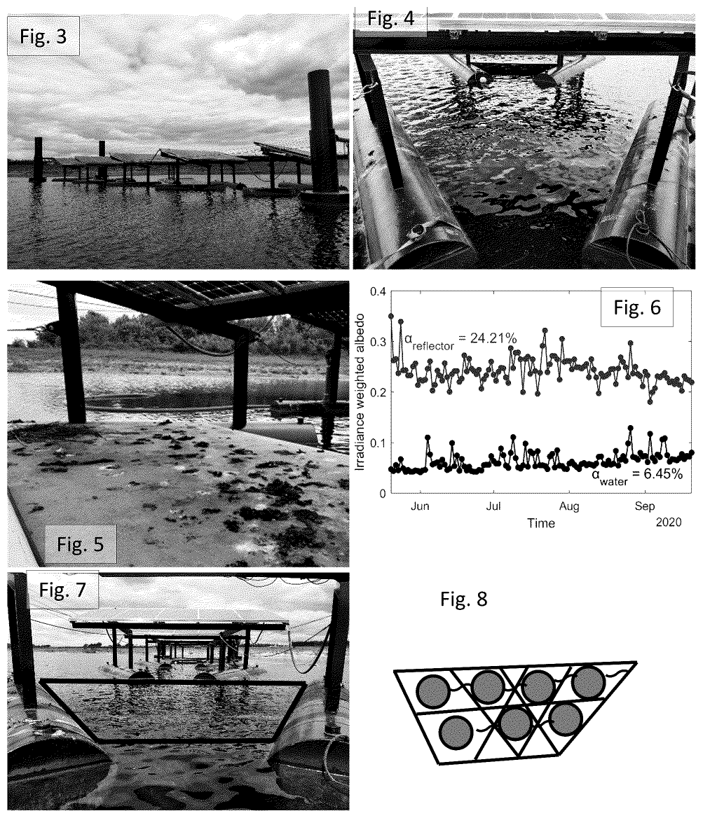

FIG. 3 shows a floating PV-system, near Weurt, the Netherlands. FIG. 4 shows a detail thereof, including two floaters nearby. FIG. 5 shows pollution of a reflector, as well as oxidation thereof.

FIG. 6 shows measured albedos of water and a rigid reflector, which its albedo had been measured to be ˜60% by the time of installation, representing considerable drop of albedo of reflector due to dirt.

FIG. 7 shows the position of the ball net-reflector indicated underneath a PC-system, having 5 PV-modules of regular size, and FIG. 8 shows a schematic representation of such a ball-net reflector.

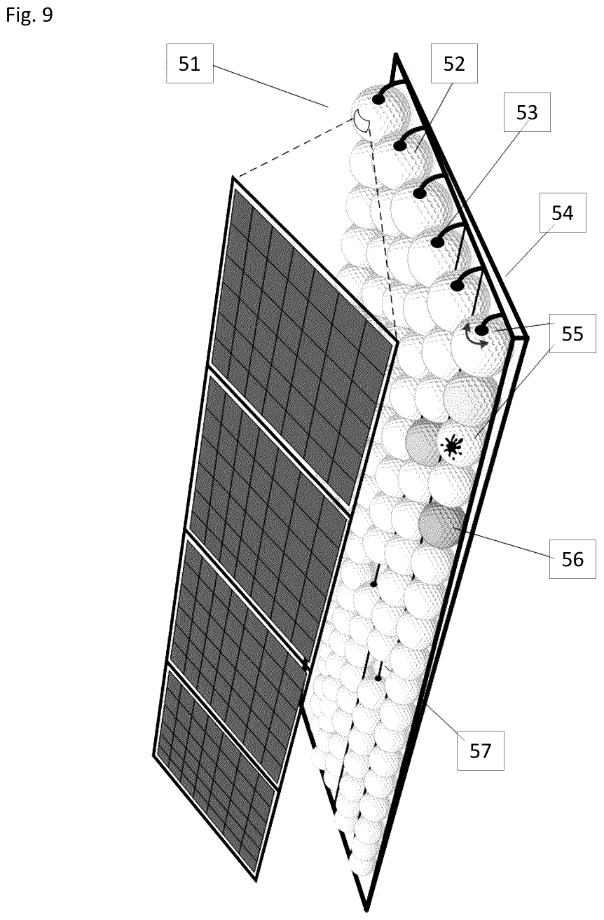

FIG. 9 shows an overview.

The figures are further detailed in the description.
The invention although described in detailed explanatory context may be best understood in conjunction with the accompanying figures.

It should be appreciated that for commercial application it may be preferable to use one or more variations of the present system, which would be similar to the ones disclosed in the present application and are within the spirit of the invention.

1. A ball-net reflector for a bifacial PV-system comprising
a plurality of balls, each ball having at least one ball-albedo,
at least one ball-fixator per ball, the ball-fixator adapted to substantially keep the at least one ball of the plurality of balls into a stationary place,
an optional matrix structure with openings adapted to receive the plurality of balls, the at least one ball-fixator attached to at least one of the matrix structure and an adjacent ball, and
at least one connector for connecting the ball-net reflector to the bifacial PV-system,
wherein a view factor of a rear-side of the bifacial PV-system is 10-50%.

2. The ball-net reflector according to claim 1, wherein the PV-system comprises 2-2¹⁰ PV-modules, and a PV-system supporting structure.

3. The ball-net reflector according to claim 1, wherein the plurality of balls is arranged in a matrix with adjacent balls.

4. The ball-net reflector according to claim 1, comprising a first ball and at least one adjacent ball, wherein the at least one adjacent ball has a ball-albedo different from the ball-albedo of the first ball.

5. The ball-net reflector according to claim 3, wherein in the matrix the ball-albedo varies in a regular 2D-pattern.

6. The ball-net reflector according to claim 1, wherein the ball fixator is at least one of a string and a spring, and
wherein 2-6 ball-fixators per ball are provided, and
wherein the ball fixator is adapted to provide limited rotation of 1-30 degrees in both an azimuth and altitude direction relative to a gravitational axis, and
wherein a ball each individually is at least partly filled with a filler with a specific mass larger than air, and
wherein each ball is at least one of individually substantially spherical and individually comprising regular faces, and
wherein balls each individually have a diameter of 3-30 cm, and
wherein balls each individually float, and
wherein the at least one connector is a hook.

7. The ball-net reflector according to claim 1, wherein the ball-net reflector has an open area of 10-40% relative to a total area for passing through sunlight.

8. The ball-net reflector according to claim 7, wherein a view factor of a rear-side of the bifacial PV-system is 25-40%.

9. The ball-net reflector according to claim 1, wherein 10-35% of the plurality of balls has a first ball-albedo, and wherein 10-35% of the plurality of balls has a second ball-albedo, and wherein 10-35% of the plurality of balls has a third ball-albedo, and
wherein 10-35% of the plurality of balls has a fourth ball-albedo,
and
wherein 10-35% of the plurality of balls has a fifth ball-albedo.

10. The ball-net reflector according to claim 1, wherein each ball individually is adapted to reflect at least one of solar light and ambient light, respectively, and
wherein each ball individually comprises a coating for diffuse reflection, and
wherein each ball individually comprises a textured surface for diffuse reflection.

11. The ball-net reflector according to claim 1, wherein each ball individually is adapted to reflect at least one bandwidth of wavelength, wherein the bandwidth is <300 nm.

12. The ball-net reflector according to claim 11, wherein a central wavelength of a bandwidth of a first ball is selected from at least one of 470±20 nm, 470±20 nm, 980±20 nm, 850±20 nm, 1170±20 nm, 785±20 nm, 705±20 nm, 675±20 nm, 630±20 nm, 360±20 nm, 550±20 nm, and 1050±20 nm, and combinations thereof.

13. The ball-net reflector according to claim 1, wherein each ball individually is adapted to reflect low intensity light.

14. The ball-net reflector according to claim 1, wherein the ball-net reflector is adapted to provide buoyance to the PV-system.

15. A PV-system comprising at least one Ball-net reflector according to claim 1.

16. The ball-net reflector according to claim 1, wherein the plurality of balls is not arranged in a matrix with adjacent balls.
